(19) United States
(12) Patent Application Publication
(10) Pub. No.: US 2020/0388742 A1
(43) Pub. Date: Dec. 10, 2020

(54) METHOD FOR PRODUCING THERMOELECTRIC MODULES

(71) Applicant: Mahle International GmbH, Stuttgart (DE)

(72) Inventors: Juergen Gruenwald, Ludwigsburg (DE); Michael Moser, Ellwangen (DE); Thomas Pfadler, Stuttgart (DE)

(21) Appl. No.: 16/492,106

(22) PCT Filed: Mar. 6, 2018
(86) PCT No.: PCT/EP2018/055395

§ 371 Date: Sep. 6, 2019

(30) Foreign Application Priority Data
Mar. 7, 2017 (DE) 10 2017 203 643.5

(51) Int. Cl. H01L 35/34; H01L 35/32

(52) U.S. Cl. CPC H01L 35/34; H01L 35/32

(57) ABSTRACT

A method for producing thermoelectric modules of a thermoelectric device may include providing an electrically conductive carrier, applying a thermoelectrically active semiconductor onto a side of the carrier by a vacuum-based coating method, and dividing the carrier, with the semiconductor thereon, into a plurality of parts so that each part may form a thermoelectric module with a carrier portion and a semiconductor portion.

### CROSS-REFERENCE TO RELATED APPLICATIONS

This application claims priority to International Patent Application No. PCT/EP2018/055395, filed on Mar. 6, 2018, and German Patent Application No. DE 10 2017 203 643.5, filed on Mar. 7, 2017, the contents of both of which are hereby incorporated by reference in their entirety.

### TECHNICAL FIELD

The present invention relates to a method for producing thermoelectric modules of a thermoelectric device. The invention further relates to a method for producing such a thermoelectric device. In addition, the invention relates to such a thermoelectric module and such a thermoelectric device.

### BACKGROUND

Thermoelectric devices are used in a variety of applications, for example in vehicles. Owing to their comparatively high efficiency, the areas of use of such devices are constantly increasing. Thermoelectric devices usually have a plurality of thermoelectric modules and permit the conversion of a temperature difference into an electric voltage or respectively an electric current and/or vice versa. On application of an electric voltage to such a device, a temperature difference occurs, described by the Peltier effect, which can be used for example for the temperature regulation of objects and fluids, in particular in vehicles. When different temperatures prevail on different sides of such a device, an electric voltage or respectively an electric current can be tapped on the device, described by the Seebeck effect.

For the function of such devices, said modules are necessary, which comprise respectively a thermoelectrically active material. The thermoelectrically active material is generally a semiconductor, which has a corresponding doping. Usually, several such modules are electrically contacted with one another, in order to achieve and intensify the said effects. In addition to the thermoelectrically active material, electric contacts between the modules are therefore necessary.

The production of the respective modules and of the device play a role in the increase in efficiency and cost reduction of such devices and modules.

From U.S. Pat. No. 3,436,327 A it is known to produce thin layer systems by means of applying various layers on a substrate and subsequent selective removal of undesired layers.

DE 10 2012 105 373 A1 proposes, for the production of a thermoelectric module, the provision of an electrically insulating substrate, the applying of an electric conductor on the substrate, the introducing of a break into the electric conductor and the introducing of a thermoelectrically active semiconductor into the break.

From US 2015/0325773 A1 a thermoelectric film is known, which is produced by the applying of a semiconductor layer on a substrate. The film is subsequently shaped and cubed, wherein the parts which are thereby produced are used for the production of a thermoelectric device.

JP H08-64875 A describes a method for producing a thermoelectric device. Here, an electrode plate and a semiconductor plate are provided respectively with recesses and are subsequently bonded to one another.

US 2006/0124165 A1 proposes, for the production of thermoelectric modules, providing a wafer of thermoelectrically active material and applying a carrier on the wafer. The structure is subsequently divided for the production of the modules.

US 2010/0319744 A1 proposes, for the production of thermoelectric modules, securing to one another two wafers from a semiconductor by a connecting layer, and subsequently dividing the structure.

The production methods known from the prior art therefore require a plurality of individual method steps for the production of the respective module. Furthermore, the methods are complicated by the local application of the respective layer, in particular of the thermoelectrically active semiconductor. In addition, the local application always leads to material losses, so that the methods are comparatively uneconomical.

### SUMMARY

The present invention is therefore concerned with the problem of indicating, for a method for producing thermoelectric modules and a method for producing a thermoelectric device and for such a module and such a device, improved or at least different embodiments, which are distinguished in particular by a simplified and cost-effective implementation.

This problem is solved according to the invention by the subjects of the independent claims. Advantageous embodiments are the subject of the dependent claims.

The present invention is based on the general idea of producing a plurality of thermoelectric modules of a thermoelectric device by the applying of a thermoelectrically active material onto a common carrier, and the subsequent dividing of the carrier into a plurality of parts, which respectively form such a module. The applying of the thermoelectrically active material onto the carrier, which is large at least compared to the respective module, permits in particular an application of the thermoelectrically active material over a large area, so that it can be applied in a simplified manner and/or without losses or at least with reduced losses. In addition to a simplified production of the modules, this leads to a cost reduction of the production of the modules and therefore of an associated thermoelectric device. The choice of an electrically conductive carrier leads, in addition, to the fact that an electrically conductive carrier portion is present in the respective module after the dividing, on which carrier portion a portion of the thermoelectrically active material is applied. Therefore, in the respective module a material transition is already present, which is used for the thermoelectric function of the respective module or respectively of the associated thermoelectric device. In addition, the respective carrier portion can be used for the electric contacting of the respective module with other modules and/or with other components of the thermoelectric device. This leads to a further efficiency increase and simplification of the production of the modules and of the device. In particular, it is not necessary to provide the carrier with recesses, breaks and suchlike and/or to apply the thermoelectrically active material locally onto the carrier. In addition the number of components of the respective thermoelectric module and/or of the associated thermoelectric device is reduced or at least kept small.

In accordance with the idea of the invention, to produce the thermoelectric modules firstly the carrier is provided, which is electrically conductive. The carrier is configured in a disc-shape or respectively as a disc or plate. Thereafter, a thermoelectrically active semiconductor is applied as thermoelectrically active material onto one side of the carrier. The carrier, provided with the semiconductor, is then divided into a plurality of parts, so that the respective part forms one such module. Here, the respective module has a carrier portion of the carrier and a semiconductor portion of the semiconductor.

The carrier is expediently metallic. The carrier is preferably made from a metal or from a metal alloy. In particular, the carrier is made from aluminium or from an aluminium alloy.

The dividing of the carrier, provided with the semiconductor, into a plurality of parts preferably takes place in such a way that the respective part or respectively the respective module is parallelepiped-shaped. Therefore, the number of modules can be increased and/or the carrier provided with the semiconductor can be used efficiently for producing the modules.

The respective module can have any desired dimensioning. The respective module can, in particular, as mentioned above, be parallelepiped-shaped. The edge length of the respective cuboid is maximally a few millimetres here, in particular less than 5 mm, for example 1 mm or 0.5 mm.

In an advantageous further development of the solution according to the invention, before the dividing, an electrically conductive cover layer is applied on the side of the semiconductor facing away from the carrier. This takes place in such a way that, after the dividing, each module additionally has a cover layer portion of the cover layer. This means that the respective module has an electrically conductive carrier portion and an electrically conductive cover layer portion, between which the thermoelectrically active semiconductor is arranged. The electrically conductive cover layer portion of the respective module constitutes an additional material transition in the respective module. Accordingly, the efficiency of the respective module can be hereby increased. In addition, the respective cover layer portion can be used for the electric contacting of the respective module with other modules or respectively components of an associated thermoelectric device.

The cover layer can consist of or be produced from any desired electrically conductive material. In particular, the cover layer can be made from the same material as the carrier. The cover layer is made, for example, from aluminium or from an aluminium alloy.

Of course, further layers can be applied on the carrier before the applying of the semiconductor and/or on the semiconductor and/or on the cover layer and/or on the respective module, which further layers are necessary or advantageous for the function and/or stability of the modules. This includes adhesion promoters which are applied onto the carrier and/or on the semiconductor. A further example are diffusion barriers, which are provided between the semiconductor and the carrier and/or the cover layer.

Embodiments are preferred in which the thickness of the cover layer corresponds to the thickness of the carrier. This means that the cover layer is applied in such a way that a cover layer thickness of the cover layer corresponds to a carrier thickness of the carrier. Consequently, it is preferred if the cover layer thickness of the respective cover layer portion corresponds to the carrier thickness of the respective carrier portion. The thickness runs here in the direction of the normal of the side of the carrier or respectively of the side of the semiconductor. Such a production of the respective module permits in particular a simplified production of an associated thermoelectric device.

Embodiments are advantageous in which the semiconductor is applied on the entire side of the carrier. Therefore, the carrier is used in entirety for producing the modules and consequently material losses and inefficiencies are reduced.

The same applies for the cover layer, which is preferably applied on the entire side of the semiconductor facing away from the carrier.

The semiconductor can basically be applied onto the carrier in any desired manner.

According to the invention, the semiconductor is applied onto the carrier by means of a vacuum-based coating method. Particularly preferably, the semiconductor is applied onto the carrier by sputtering, in particular by magnetron sputtering, as described for example in Surface & Coatings Technology 204 (2010) 1661-1684. In addition to an applying of the semiconductor onto the carrier over a large area, this permits an increased quality of the semiconductors and therefore of the modules and of the associated thermoelectric device.

The cover layer can basically be applied onto the semiconductor in any desired manner. In particular, the cover layer can be applied onto the semiconductor by means of a vacuum-based coating method. This includes sputtering, in particular magnetron sputtering. In an analogous manner to the applying of the semiconductor onto the carrier, such coating methods permit an application over a large area and/or an increased quality of the cover layer.

Basically, the dividing of the carrier, provided with the semiconductor, wherein the semiconductor is provided, if applicable, with the cover layer, can take place in any desired manner. This means that any desired tools and means can come into use for the dividing. In particular, it is conceivable to implement the dividing by means of a laser beam.

It is conceivable to implement the dividing by means of sawing and/or cutting. These variants permit a simple and cost-effective and precise division.

Variants are conceivable, in which at least one cut is introduced, in order to produce at least two modules. It is also conceivable to introduce a plurality of such cuts, in order to produce more than two modules.

Advantageous embodiments make provision that, for the dividing, at least one longitudinal cut, running in longitudinal direction, and one transverse cut, running in a transverse direction running transversely to the longitudinal direction, are introduced. It is particularly advantageous if, for the dividing, at least two longitudinal cuts, running in longitudinal direction and spaced apart from one another in transverse direction and/or at least two transverse cuts, running in transverse direction and spaced apart in longitudinal direction, are introduced. Therefore, a plurality of such modules is produced from the same carrier, provided with the semiconductor and if applicable with the cover layer.

Embodiments are advantageous, in which the longitudinal cuts and/or the transverse cuts, preferably the longitudinal cuts and the transverse cuts, are introduced equidistantly. Therefore it is possible to produce at least a majority of the modules as identical parts, which have a substantially identical dimensioning Hereby, it is also possible to produce in as efficiently a manner as possible several such modules from the carrier, provided with the semiconductor and if applicable with the cover layer. When the longitudinal cuts and the transverse cuts are introduced equidistantly, this leads, in addition, to a substantially square cross-section of the modules.

Embodiments are preferred in which the cut spacing of the longitudinal cuts and of the transverse cuts with respect to one another is selected in such a way that the modules have a thickness, also designated as module thickness, which differs from a width and/or a length of the modules. This means in particular that the modules are not configured in a cubic shape. The thickness runs here in transition direction of the components of the modules. The module thickness is therefore composed of the thickness of the carrier portion and of the semiconductor portion and, if applicable, of the cover layer portion. Hereby, in particular faults in the use of the modules through incorrect mounting are prevented or at least reduced.

Of course, it is possible to process the modules after the division, in order for example to remove undesired edges and material residues. For this, the modules can be polished and/or lapped for example. Chemical processing steps are likewise conceivable, in particular for cleaning and/or etching. Here, it is possible to remove or adapt undesired material transitions and/or geometries arising through the division, for example undesired metal semiconductor edges.

To produce such a thermoelectric device, firstly modules are produced with different thermoelectrically active semiconductors and are subsequently contacted electrically with one another.

It is conceivable to firstly produce such modules which respectively have a p-doped P-semiconductor portion. This means that the respective carrier has such a carrier portion, a P-semiconductor portion and if applicable a cover layer portion. For this, to produce the modules, a p-doped P-semiconductor is applied as thermoelectrically active semiconductor onto the carrier. In addition, such modules are produced with respectively an n-doped N-semiconductor portion. This means that the respective carrier has such a carrier portion, an N-semiconductor portion and if applicable a cover layer portion. For this, an n-doped N-semiconductor is applied onto the carrier. Subsequently, the modules are arranged and serially connected electrically, in such a way that alternately one such module with a P-semiconductor portion and one such module with an N-semiconductor portion are contacted with one another.

The electric contacting of the modules preferably takes place via the respective carrier portion and/or via the cover layer portion which is present if applicable. This leads to a simplified and cost-effective structure of the thermoelectric device. Furthermore, the number of components of the device can therefore be reduced.

The electric connecting of the modules and if applicable a mechanical connection of the modules with one another can take place in any desired manner.

Variants are conceivable, in which conductor bridges are used for this, which electrically contact and/or mechanically connect adjacent modules.

It is conceivable to provide an electrically conductive rib structure, which has opposite base sides which are connected with one another by legs arranged between the base sides, wherein the modules are integrated in the base sides or in the legs and are connected therewith electrically and/or mechanically. It is also conceivable to arrange the modules on the base sides and/or legs and to connect them therewith electrically and/or mechanically.

In further variants, the modules are electrically contacted with one another with at least one electrically conductive thread and/or mechanically connected, wherein the thread is a component of a fabric. The at least one electrically conductive thread forms said fabric here, preferably with other, in particular electrically insulating threads.

It shall be understood that in addition to the method for producing the thermoelectric modules and the method for producing the thermoelectric device, also such a module and such a device belong to the scope of this invention.

Further important features and advantages of the invention will emerge from the subclaims, from the drawings and from the associated figure description with the aid of the drawings.

It shall be understood that the features mentioned above and to be explained further below are able to be used not only in the respectively indicated combination, but also in other combinations or in isolation, without departing from the scope of the present invention.

Preferred example embodiments of the invention are illustrated in the drawings and are explained further in the following description, wherein the same reference numbers refer to identical or similar or functionally identical components.

### BRIEF DESCRIPTION OF THE DRAWINGS

There are shown, respectively diagrammatically

FIG. 1 a side view in a first method step for producing thermoelectric modules,

FIG. 2 a top view in the first method step,

FIG. 3 the view of FIG. 1 after a subsequent method step,

FIG. 4 the view of FIG. 1 in the state shown in FIG. 3,

FIG. 5 the view of FIG. 3 according to a further method step,

FIG. 6 the view of FIG. 4 according to the state shown in FIG. 5,

FIG. 7 a side view after a further method step,

FIG. 8 the view of FIG. 3 in another example embodiment,

FIG. 9 a top view according to the state shown in FIG. 8,

FIG. 10 the view of FIG. 5 in the further example embodiment,

FIG. 11 a top view in the state shown in FIG. 10,

FIG. 12 the view of FIG. 7 in the further example embodiment,

FIG. 13 a section through a thermoelectric device,

FIG. 14 the section of FIG. 13 in another example embodiment of the device.

### DETAILED DESCRIPTION

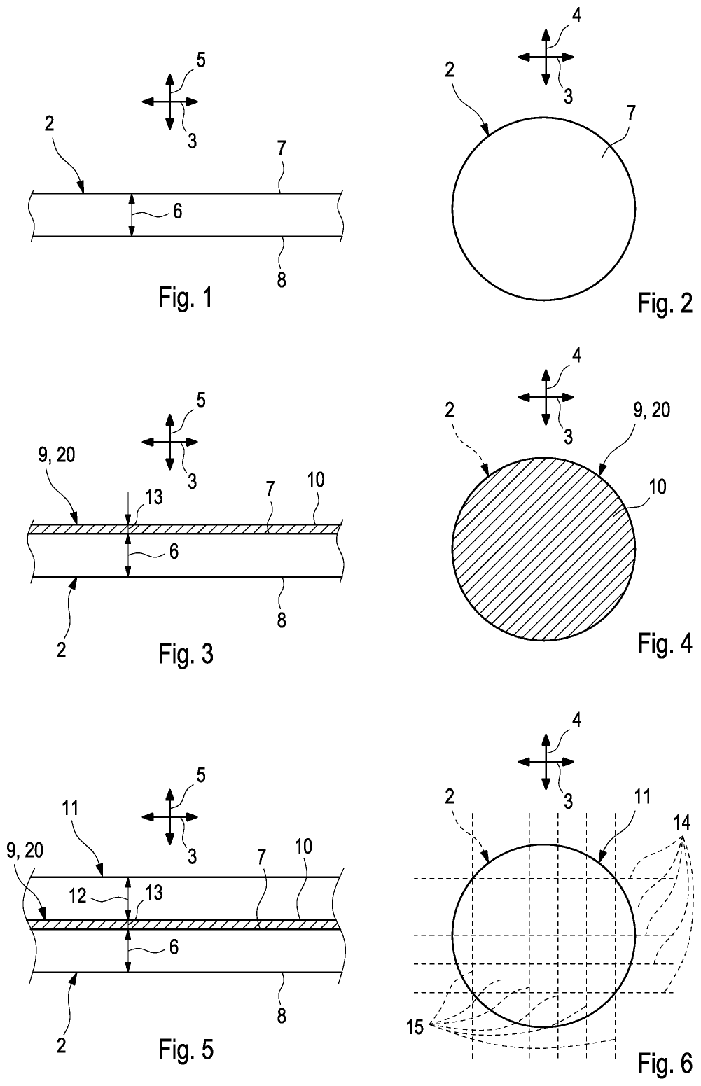

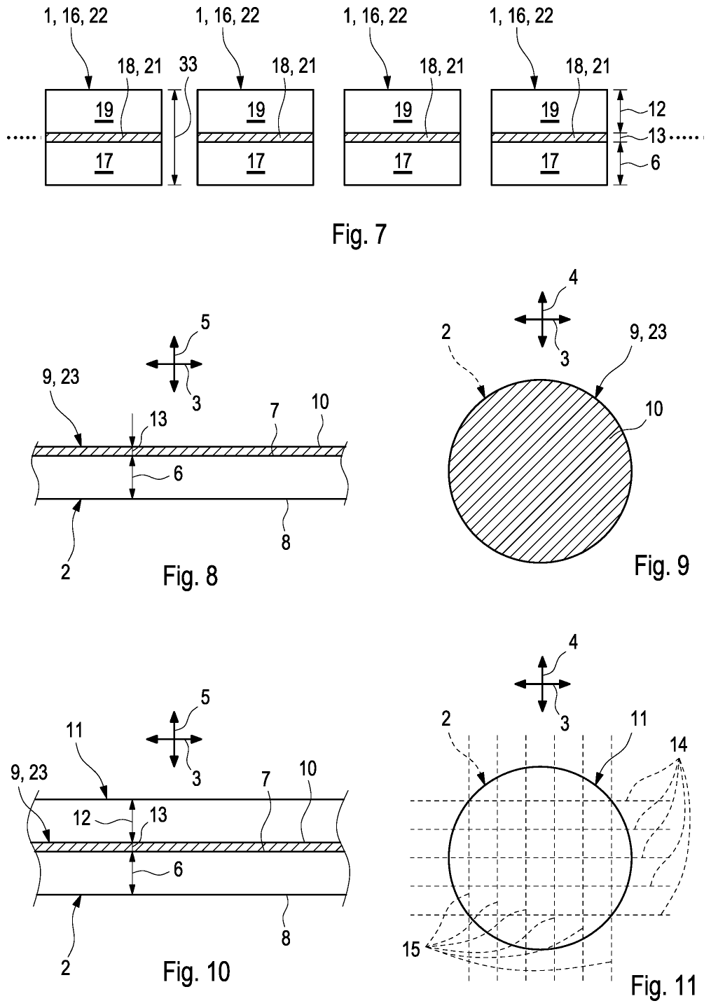

For producing thermoelectric modules 1, as are to be seen in FIG. 7, an electrically conductive carrier 2 is provided according to FIGS. 1 and 2. The electrically conductive carrier 2 is made for example from aluminium or from an aluminium alloy and, in the example which is shown, has a plate-like disc shape. This means that the dimensionings of the carrier 2 running in a longitudinal direction 3 and in a transverse direction 4 running transversely to the longitudinal direction 3 are greater than a thickness 6 of the carrier 2 running along a vertical direction 5 transversely to the longitudinal direction 3 and transversely to the transverse direction 4, also designated below as carrier thickness 6. The carrier 2 has an upper side 7 and a lower side 8 facing away from the upper side 7, which are spaced apart in vertical direction 5. According to the invention, a thermoelectrically active semiconductor 9 is applied onto one of the sides 7, 8 of the carrier 2, in the present example onto the upper side 7, which is also designated in abbreviated manner below as side 7. FIGS. 3 and 4 show here a state after the applying of the semiconductor 9. Here, it can be seen that the semiconductor 9 is applied onto the entire side 7, in such a way that the semiconductor 9 covers the side 7 entirely. The semiconductor 9 is preferably applied by means of a vacuum-based coating method, in particular sputtering, for example magnetron sputtering.

Thereafter, an electrically conductive cover layer 11 is applied onto a side 10 of the semiconductor 9 facing away from the carrier 2, wherein FIGS. 5 and 6 show a state after the applying of the cover layer 11. It can be seen that the cover layer 11 is applied onto the entire side 10 of the semiconductor 9 facing away from the carrier 2, in such a way that the cover layer 11 covers the side 10 entirely. The cover layer 11 is preferably applied by means of a vacuum-based coating method, for example sputtering, in particular magnetron sputtering. It can be seen that the cover layer 11 has substantially the same dimensioning as the carrier 2. In particular, a thickness 12 of the cover layer 11, running in vertical direction 5, subsequently designated as cover layer thickness 12, corresponds to the carrier thickness 6. In contrast, a thickness 13 of the semiconductor 9 running in vertical direction 5, designated below as semiconductor thickness 9, is substantially smaller than respectively the carrier thickness 6 and the cover layer thickness 12.

In a subsequent method step, which is indicated in FIG. 6, a dividing takes place of the carrier 2, provided with the semiconductor 9 and with the cover layer 11. The dividing takes place in the example shown by means of cuts 14, 15, which are indicated in FIG. 6 by dashed lines and which can be introduced by sawing or cutting. Here, longitudinal cuts 14 running in longitudinal direction 3 and spaced apart in transverse direction 4, and transverse cuts 15 running in transverse direction 4 and spaced apart in longitudinal direction 3 are introduced. In FIG. 6, purely by way of example, five longitudinal cuts 14 and six transverse cuts 15 can be seen. In the example which is shown, the longitudinal cuts 14 and the transverse cuts 15 are introduced respectively with an equal distance or respectively equidistantly.

The dividing of the carrier 2, provided with the semiconductor 9 and with the cover layer 11 takes place, as illustrated in FIG. 7, in such a way that several parts 16 arise, wherein the respective part 16 forms one such module 1. The respective module 1 has a carrier portion 17 of the carrier 7, a semiconductor portion 18 of the semiconductor 9 and a cover layer portion 19 of the cover layer 11. In the example which is shown, the respective module 1 is configured substantially so as to be parallelepiped-shaped, wherein the spacing of the cuts 14, 15 is preferably selected in such a way that a majority of the modules 1 has a square cross-section (see FIG. 6). It can also be seen that the thickness of the respective carrier portion 17 corresponds to the carrier thickness 6 and the thickness of the respective cover layer portion 19 corresponds to the cover layer portion thickness 12. In addition, the thickness of the respective semiconductor portion 18 corresponds to the semiconductor thickness 13. Furthermore, a thickness 33 of the respective module 1, which is composed of the thickness of the carrier portion 17, the thickness of the semiconductor 18 and the thickness of the cover layer portion 19, is different from, in particular smaller than a width which is not visible, running transversely to the thickness, and a length of the module 1, which is not visible, running transversely to the thickness and transversely to the width. This means that the modules 1 are not configured in a cube shape.

The thermoelectrically active semiconductor 9 can be a p-doped P-semiconductor 20. Accordingly, the respective module 1 has a P-semiconductor portion 21 and is also designated below as P-module 22.

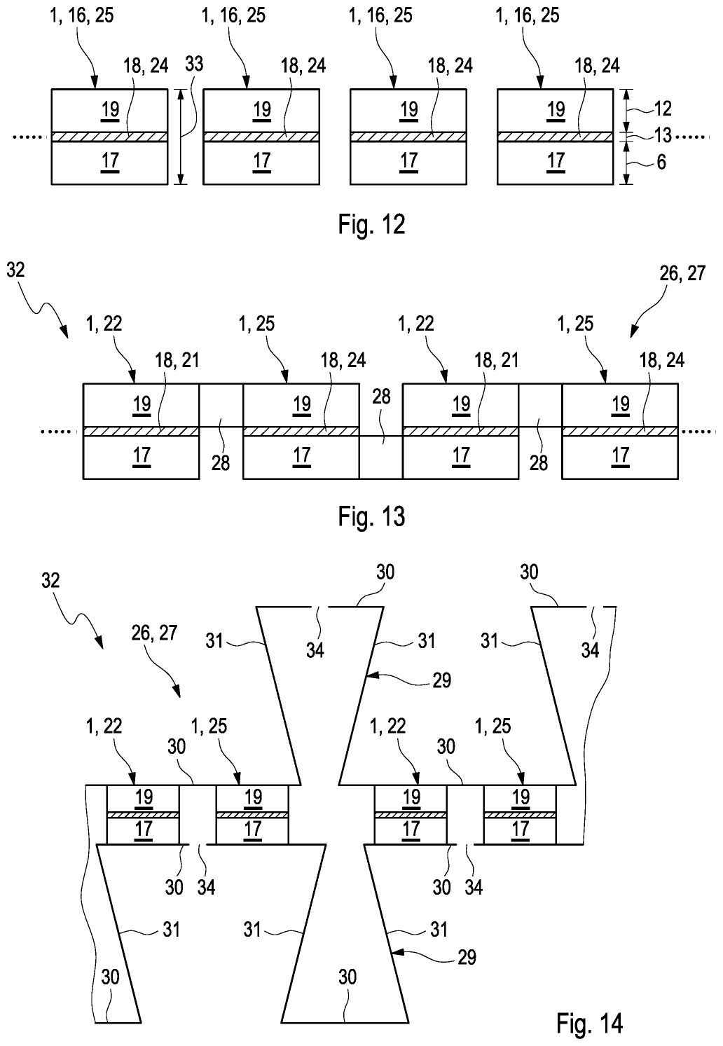

According to FIGS. 8 to 12, in an analogous manner a plurality of such modules 1 can be produced with a different thermoelectrically active semiconductor 9. In FIGS. 8 to 12, here instead of the P-semiconductor 20 applied in FIGS. 3 to 7, an n-doped N-semiconductor 23 is applied. The electrically conductive carrier 2 can correspond here to the carrier of FIGS. 1 to 6. In the state shown in FIGS. 10 and 11, the electrically conductive cover layer 11 is applied, which can correspond to the cover layer 11 of FIGS. 5 and 6. The cover layer thickness 12 of this cover layer 11 can, as previously explained, correspond to the carrier thickness 6 of the carrier 2. The dividing can, as indicated in FIG. 11, also take place by the introducing of the cuts 14, 15, wherein the dividing leads to parts 16 arising, which respectively form one such module 1, wherein the respective module 1 has one such carrier portion 17, one such semiconductor portion 18 and one such cover layer portion 19. As the N-semiconductor 23 was applied as semiconductor 9, the respective module 1 has an N-semiconductor portion 24 and is therefore designated below as N-module 25.

According to FIG. 13, for producing a thermoelectric device 26, for example a Peltier element 27, such P-modules 22 and such N-modules 25 are arranged alternately and are connected serially with one another, which means that one such P-module 22 and one such N-module 25 are electrically contacted in succession. Here, in FIG. 13 four such modules 1 can be seen, purely by way of example. The electric connecting of the modules 1 takes place via the associated carrier portion 17 and cover layer portion 19. Here, the individual modules 1 in the example shown are electrically contacted with the aid of conductor bridges 28 and connected mechanically if applicable.

In FIG. 14 a different example embodiment of the thermoelectric device 26, in particular of the Peltier element 27, can be seen. This example embodiment differs from the example embodiment shown in FIG. 13 in particular in that the electric connecting of the modules 1 takes place with the aid of two rib structures 29, spaced apart from one another and respectively electrically conductive, between which the modules 1 are arranged. The respective rib structure 29 has two base sides 30, spaced apart from one another, which are connected with one another via legs 31. In the example shown, the modules 1 are arranged between the base sides 30 of the spaced-apart rib structures 29 and are contacted electrically therewith. This can be realized in that the respective carrier portion 17 or respectively cover layer portion 19 is electrically connected with the base side 30 of the rib structure 29, in particular is mounted directly thereon.

For the serial electric connecting of the modules 1, the base sides 30 of one of the rib structures 29, facing away from the modules 1 or respectively remote therefrom, and the base sides 30 of the other rib structure 29 facing the modules 1 or respectively adjacent thereto, are respectively interrupted electrically by a break 23, wherein it is conceivable to provide such breaks 34 alternatively in the legs 31 (not shown). It is also conceivable to fill at least one of the breaks 34 with an electrically insulating filling material, which is not shown, in particular with a dielectric.

The thermoelectric devices 26 shown in FIGS. 13 and 14 can be respectively a component of a heat exchanger 32, for example in a vehicle, which is not shown further. In the example shown in FIG. 14, the respective rib structure 29 can be flowed through by a fluid, in such a way that a heat exchange occurs between the fluids.

1.-13. (canceled)

14. A method for producing thermoelectric modules of a thermoelectric device, the method comprising:
providing an electrically conductive carrier;
applying a thermoelectrically active semiconductor onto a side of the carrier by a vacuum-based coating method; and
dividing the carrier, with the semiconductor thereon, into a plurality of parts so that each part forms a thermoelectric module with a carrier portion and a semiconductor portion.

15. The method according to claim 14, further comprising, before the dividing, applying an electrically conductive cover layer on a side of the semiconductor facing away from the carrier so that, after the dividing, each thermoelectric module has in addition a cover layer portion.

16. The method according to claim 15, wherein the cover layer is applied in such a way that a cover layer thickness of the cover layer corresponds to a carrier thickness of the carrier.

17. The method according to claim 14, wherein the semiconductor is applied on an entire side of the carrier.

18. The method according to claim 15, wherein the cover layer is applied on an entire side of the semiconductor facing away from the carrier.

19. The method according to one of claim 14, wherein the dividing includes introducing at least two longitudinal cuts running in a longitudinal direction and spaced apart from one another in a transverse direction running transversely to the longitudinal direction, and at least two transverse cuts running in the transverse direction and spaced apart in the longitudinal direction.

20. The method according to claim 19, wherein at least one of: (i) the longitudinal cuts are introduced equidistantly; and (ii) the transverse cuts are introduced equidistantly.

21. The method according to claim 14, wherein the dividing is done by sawing or cutting.

22. The method according to claim 14, wherein the carrier is made from a metal or a metal alloy.

23. A method for producing a thermoelectric device, the method comprising:
producing first thermoelectric modules by:
providing an electrically conductive carrier;
applying a p-doped P-semiconductor onto a side of the carrier by a vacuum-based coating method; and
dividing the carrier, with the P-semiconductor thereon, into a plurality of parts so that each part forms one of the first thermoelectric modules with a carrier portion and a semiconductor portion;
producing second thermoelectric modules by:
providing an electrically conductive carrier;
applying an n-doped N-semiconductor onto a side of the carrier by the vacuum-based coating method; and
dividing the carrier, with the N-semiconductor thereon, into a plurality of parts so that each part forms one of the second thermoelectric modules with a carrier portion and a semiconductor portion; and
arranging and serial electric connecting the first and second thermoelectric modules in such a way that alternately one first electric module and one second electric module are contacted with one another.

24. A thermoelectric module of a thermoelectric device, the thermoelectric module being produced by a process comprising:
providing an electrically conductive carrier;
applying a thermoelectrically active semiconductor onto a side of the carrier by a vacuum-based coating method; and
dividing the carrier, with the semiconductor thereon, into a plurality of parts so that each part forms a thermoelectric module with a carrier portion and a semiconductor portion.

25. A thermoelectric device for a heat exchanger, the thermoelectric device being produced by a process comprising:
producing first thermoelectric modules by:
providing an electrically conductive carrier;
applying a p-doped P-semiconductor onto a side of the carrier by a vacuum-based coating method; and
dividing the carrier, with the P-semiconductor thereon, into a plurality of parts so that each part forms one of the first thermoelectric modules with a carrier portion and a semiconductor portion;
producing second thermoelectric modules by:
providing an electrically conductive carrier;
applying an n-doped N-semiconductor onto a side of the carrier by the vacuum-based coating method; and
dividing the carrier, with the N-semiconductor thereon, into a plurality of parts so that each part forms one of the second thermoelectric modules with a carrier portion and a semiconductor portion; and
arranging and serial electric connecting the first and second thermoelectric modules in such a way that alternately one first electric module and one second electric module are contacted with one another.

26. The thermoelectric module according to claim 24, wherein the process further comprises, before the dividing, applying an electrically conductive cover layer on a side of the semiconductor facing away from the carrier so that, after the dividing, each thermoelectric module has in addition a cover layer portion.

27. The thermoelectric module according to claim 26, wherein the cover layer is applied in such a way that a cover layer thickness of the cover layer corresponds to a carrier thickness of the carrier.

28. The thermoelectric module according to claim 24, wherein the semiconductor is applied on an entire side of the carrier.

29. The thermoelectric module according to claim 26, wherein the cover layer is applied on an entire side of the semiconductor facing away from the carrier.

30. The thermoelectric module according to one of claim 24, wherein the dividing includes introducing at least two longitudinal cuts running in a longitudinal direction and spaced apart from one another in a transverse direction running transversely to the longitudinal direction, and at least two transverse cuts running in the transverse direction and spaced apart in the longitudinal direction.

31. The method according to claim 30, wherein at least one of: (i) the longitudinal cuts are introduced equidistantly; and (ii) the transverse cuts are introduced equidistantly.

32. The method according to claim 24, wherein the dividing is done by sawing or cutting.

33. The method according to claim 24, wherein the carrier is made from a metal or a metal alloy.
